(19) United States
(12) Patent Application Publication
(10) Pub. No.: US 2008/0258304 A1
(43) Pub. Date: Oct. 23, 2008

(54) Semiconductor device having multiple wiring layers

(75) Inventors: Atsushi KOMURA, Kariya-city (JP); Takeshi KUZUHARA, Nukata-gun (JP); Takayoshi NARUSE, Okazaki-city (JP); Mitsutaka KATADA, Hoi-gun (JP)

Correspondence Address: POSZ LAW GROUP, PLC, 12040 SOUTH LAKES DRIVE, SUITE 101, RESTON, VA, 20191, US

(73) Assignee: DENSO CORPORATION, Kariya-city (JP)

(21) Appl. No.: 12/081,809

(22) Filed: Apr. 22, 2008

(30) Foreign Application Priority Data
Apr. 23, 2007 (JP) 2007-112784
Mar. 13, 2008 (JP) 2008-64209

(51) Int. Cl. H01L 23/48

(52) U.S. Cl. 257/751; 257/E23.01

(57) ABSTRACT

A semiconductor device includes: a substrate; and wiring layers on the substrate. Each wiring layer includes: an interlayer insulation film having a wiring groove with a via hole; a copper wiring in the groove and the hole; an barrier metal layer between an inner wall of the groove with the hole and the copper wiring; and an upper barrier metal layer on the interlayer insulation film and covering an upper surface of the copper wiring. The barrier metal layer prevents a copper component in the copper wiring from diffusing into the interlayer insulation film. The copper wiring of an upper layer is electrically coupled with the copper wiring of a lower layer. The upper barrier metal layer of the lower layer prevents a copper component in the copper wiring of the lower layer from diffusing into the interlayer insulation film of the upper layer.

### CROSS REFERENCE TO RELATED APPLICATIONS

This application is based on Japanese Patent Applications No. 2007-112784 filed on Apr. 23, 2007, and No. 2008-64209 filed on Mar. 13, 2008, the disclosures of which are incorporated herein by reference.

### FIELD OF THE INVENTION

The present invention relates to a semiconductor device having multiple wiring layers.

### BACKGROUND OF THE INVENTION

A wiring of a LSI circuit is made of aluminum in a prior art. Recently, the wiring of the LSI circuit is made of copper so as to improve signal delay attributed to a capacitance between wirings and a wiring resistance. This is because that copper has a wiring resistance lower than that of aluminum.

A method for forming the wring made of copper is, for example, a copper dual damascene method, which is disclosed in JP-B2-3403058. In this method, an interlayer insulation film is formed on a semiconductor substrate. A wiring groove for forming an upper wiring is formed on the insulation film. A via hole for connecting the upper wiring and a lower wiring is formed in the insulation film. By supplying copper or copper alloy material for forming the wiring, the upper wiring is formed together with filling the via hole with the copper or the copper alloy material. Thus, a connection wiring in the via hole and the upper wiring are simultaneously formed.

FIGS. 10A to 10C show the method for forming the wiring according to the prior art. As shown in FIG. 10A, a substrate wiring 111 is formed on a semiconductor substrate 110. An interlayer insulation film 112 is formed on the substrate 110. Then, a resist pattern having a hole corresponding to a via groove 113a is formed on the insulation film 112 by a photo lithography method. By using the resist pattern as a mask, the insulation film 112 is etched, thereby, the via groove 113a is formed.

Next, as shown in FIG. 10B, a resist pattern as a mask having a large hole corresponding to a wiring groove 113 is formed on the insulation film 112 to cover the via groove 113a. By using the mask, the insulation film 112 is etched so that the substrate wiring 111 is exposed from the insulation film 112. Thus, the wiring groove 113 is formed, and the via groove 113a is connected to the substrate wiring 111.

As shown in FIG. 10C, a barrier metal layer 115 and a seed layer (not shown) for preventing wiring material from being dispersed are formed on an inner wall of the via groove 113a and the wiring groove 113. Then, copper material is filled in the via groove 113a and the wiring groove 113, and the copper material is flattened by a CMP (i.e., chemical mechanical polishing) method. Thus, a copper wiring 118 is formed such that the copper wiring 118 provides a surface wiring and a connection member in a via hole. The copper wiring 118 is integrated with the connection member. A protection film 120 as a passivation film made of P—SiN is formed on the copper wiring 118 and the insulation film 112 so that copper material is prevented from being dispersed into the insulation film 112.

When the protection film 120 is made of P—SiN, adhesiveness between the protection film 120 and the copper wiring 118 is low, so that the protection film 120 may be removed from the copper wiring 118 by applying stress in the CMP process, and/or removed from the copper wiring 118 by a blister formed on the wiring 118. To improve the adhesiveness between the protection film 120 and the copper wiring 118, an anneal process, a plasma processing process and/or the like are necessary for reforming a surface of the copper wiring 118. Thus, a manufacturing method of the wiring is complicated. Further, a diffusion pass through a boundary between the copper wiring 118 and the protection film 120 may be formed, and therefore, the copper material in the copper wiring 118 may migrate. Thus, a life time of the copper wiring 118 is shortened.

Further, as shown in FIG. 11, in an etching step for forming an upper wiring groove 113, in which an upper copper wiring 118 is embedded so that the upper copper wiring 118 provides a wiring layer on an upper insulation film 112, the upper wiring groove 113 may be formed to stick out a lower copper wiring 118. In this case, an etching region 121 is formed in the lower insulation film 112. The barrier metal layer 115 may have a defect in the etching region 121. When the barrier metal layer 115 has the defect, the upper copper wiring 118 contacts the lower insulation film 112, so that the copper material is diffused in the lower insulation film 112. Thus, device characteristics may be varied. Accordingly, in a photo lithography step before the etching step, high alignment accuracy is required to align an opening of an upper mask corresponding to the upper wiring groove 113 on an upper surface of the lower copper wiring 118.

Thus, it is required for the semiconductor device to prevent the copper material in the copper wiring 118 from penetrating into the interlayer insulation film 112.

### SUMMARY OF THE INVENTION

In view of the above-described problem, it is an object of the present disclosure to provide a semiconductor device having multiple wiring layers.

According to a first aspect of the present disclosure, a semiconductor device includes: a semiconductor substrate; and a plurality of wiring layers staked on the substrate. Each wiring layer includes: an interlayer insulation film having a wiring groove with a via hole, which penetrates the interlayer insulation film along with a thickness direction of the interlayer insulation film; a copper wiring disposed in the wiring groove and the via hole and made of copper or copper alloy; an inner wall barrier metal layer disposed between an inner wall of the wiring groove with the via hole and the copper wiring; and an upper barrier metal layer disposed on the interlayer insulation film and covering an upper surface of the copper wiring. The inner wall barrier metal layer prevents a copper component in the copper wiring from diffusing into the interlayer insulation film. The plurality of wiring layers includes an upper layer and a lower layer. The copper wiring of the upper layer is electrically coupled with the copper wiring of the lower layer. The upper barrier metal layer of the lower layer prevents a copper component in the copper wiring of the lower layer from diffusing into the interlayer insulation film of the upper layer.

In the above device, the copper component in the copper wiring of the lower layer is prevented from diffusing into the interlayer insulation film in the upper layer. Further, a manufacturing method of the device is simple, so that a manufacturing cost is also small.

According to a second aspect of the present disclosure, a semiconductor device includes: a semiconductor substrate having a substrate wiring; and first and second wiring layers staked on the substrate in this order. The substrate wiring is disposed on a principal surface of the substrate. The first wiring layer includes: a first interlayer insulation film having a first wiring groove with a first via hole, wherein the first via hole penetrates the first interlayer insulation film along with a thickness direction of the first interlayer insulation film so that the first via hole reaches the substrate wiring on the substrate; a first copper wiring disposed in the first wiring groove and the first via hole; a first inner wall barrier metal layer disposed between an inner wall of the first wiring groove with the first via hole and the first copper wiring, and disposed on a part of the substrate wiring, wherein the part of the substrate wiring is exposed in the first via hole; and a first upper barrier metal layer disposed on the first interlayer insulation film and covering an upper surface of the first copper wiring. The second wiring layer includes: a second interlayer insulation film having a second wiring groove with a second via hole, wherein the second via hole penetrates the second interlayer insulation film along with a thickness direction of the second interlayer insulation film so that the second via hole reaches the first upper barrier metal layer in the first wiring layer; a second copper wiring disposed in the second wiring groove and the second via hole; a second inner wall barrier metal layer disposed between an inner wall of the second wiring groove with the second via hole and the second copper wiring, and disposed on a part of the first upper barrier metal layer, wherein the part of the first upper barrier metal layer is exposed in the second via hole; and a second upper barrier metal layer disposed on the second interlayer insulation film and covering an upper surface of the second copper wiring. The first inner wall barrier metal layer prevents a copper component in the first copper wiring from diffusing into the first interlayer insulation film, and the second inner wall barrier metal layer prevents a copper component in the second copper wiring from diffusing into the second interlayer insulation film. The second copper wiring is electrically coupled with the first copper wiring. The first upper barrier metal layer prevents a copper component in the first copper wiring from diffusing into the second interlayer insulation film.

In the above device, the copper component in the copper wiring of the first wiring layer is prevented from diffusing into the interlayer insulation film in the second wiring layer. Further, a manufacturing method of the device is simple, so that a manufacturing cost is also small.

### BRIEF DESCRIPTION OF THE DRAWINGS

The above and other objects, features and advantages of the present invention will become more apparent from the following detailed description made with reference to the accompanying drawings. In the drawings:

FIG. 1 is a cross sectional view showing a wiring structure in a semiconductor device according to a first embodiment;

FIGS. 2A to 2C are partially enlarged cross sectional views showing a manufacturing method of the wiring structure shown in FIG. 1;

FIGS. 3A to 3C are partially enlarged cross sectional views showing the manufacturing method of the wiring structure shown in FIG. 1;

FIGS. 4A to 4B are partially enlarged cross sectional views showing the manufacturing method of the wiring structure shown in FIG. 1;

FIG. 5 is a cross sectional view showing an upper barrier metal layer functioning as an etching stopper layer, according to the first embodiment;

FIG. 6 is a partially enlarged cross sectional view showing a wiring structure in a semiconductor device according to a second embodiment;

FIG. 7 is a partially enlarged cross sectional view showing the wiring structure in FIG. 6 when alignment of a copper wiring is deviated from a proper position;

FIG. 8 is a partially enlarged cross sectional view showing a wiring structure in a semiconductor device according to a modification of the second embodiment;

FIG. 9 is a partially enlarged cross sectional view showing a wiring structure in a semiconductor device according to a second modification of the second embodiment;

FIGS. 10A to 10C are partially enlarged cross sectional views showing a manufacturing method of a wiring structure according to a prior art; and

FIG. 11 is a partially enlarged cross sectional view showing the wiring structure in FIG. 10C when alignment of a copper wiring is deviated from a proper position.

### DETAILED DESCRIPTION OF THE PREFERRED EMBODIMENTS

### First Embodiment

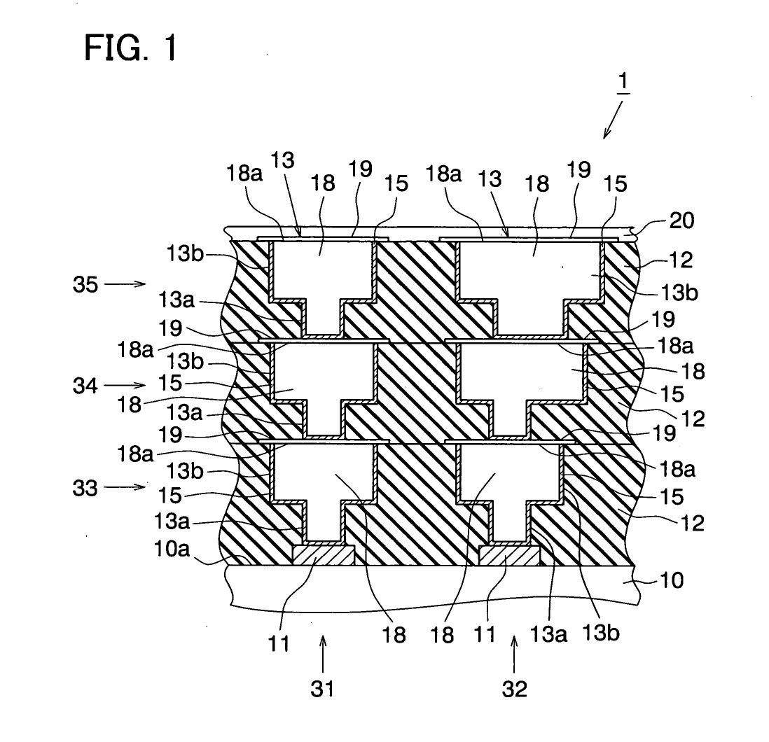

A semiconductor device 1 according to a first embodiment is shown in FIG. 1. The device is, for example, an in-vehicle combined IC having a lateral diffused MOS and a CMOS. The LDMOS as a power device and the CMOS as a normal device are formed on the same semiconductor substrate. Here, a phrase that one layer is disposed on another layer means two cases, one case that the one layer is disposed directly above the other layer, and the other case that the one layer is disposed over the other layer through a third layer therebetween.

In FIG. 1, the device 1 includes a semiconductor substrate 10, and first to third wiring layers 33-35. A CMOS element 31 and a LDMOS element 32 are formed on a principal surface 10a of the substrate 10. The first to third wiring layers 33-35 are stacked on the substrate 10 in this order. A passivation film 20 is formed on a surface of the third wiring layer 35. The passivation film 20 is made of a P—SiN film or a P-TEOS film. The detailed structure of the CMOS element 31 and the LDMOS element 32 is not shown in FIG. 1.

The first wiring layer 33 is formed on the principal surface 10a of the substrate 10. The substrate 10 is made of a SOI substrate or the like. The first wiring layer 33 includes an interlayer insulation film 12, an inner wall barrier metal layer 15, a copper wiring 18 and an upper barrier metal layer 19.

A substrate wiring 11 for connecting to the CMOS element 31 and the LDMOS element 32 is formed on the principal surface 10a.

The insulation film 12 is made of a SiO₂ film. Each insulation film 12 may have low dielectric constant so that the insulation film 12 reduces cross talk. In this case, the insulation film 12 is made of a low-k film. Thus, the insulation film 12 may be made of a TEOS film, a SiOC film, a FSG (i.e., fluorine-doped silicate glass) film, a PSG (i.e., phosphorus-contained silicate glass) film, a BPSG (i.e., boron and phosphorus-contained silicate glass) film or a SOG (i.e., spin on glass), film. Here, the SiOC film is a SiO₂ film including a large amount of carbon.

The insulation film 12 includes a wiring groove 13 having a via portion 13a and a wiring portion 13b. The via portion 13a is filled with a connection member, which connects the substrate wiring 11 and the copper wiring 18. The wiring portion 13b is filled with a predetermined pattern wiring. The wiring groove 13 penetrates the insulation film 12. The wiring portion 13b covers the via portion 13a, and a width of the wiring portion 13b is larger than a width of the via portion 13a.

It is required for the LDMOS element 32 to reduce an on-state resistance so that the LDMOS flows a large amount of current. Thus, it is necessary to increase the thickness of the copper wiring 18. Accordingly, the thickness of the insulation film 12, in which the copper wiring 18 is formed, is in a range between 1.0 μm and 2.0 μm. In this embodiment, the thickness of the insulation film 12 is 1.5 μm.

The wiring groove 13 is filled with copper material or a copper alloy material so that the copper wiring 18 is formed. Specifically, the copper wiring 18 is formed on an inner wall of the wiring groove 13 through the inner wall barrier metal layer 15. The inner wall barrier metal layer 15 is a coating film having conductivity, which is formed by a sputtering method, CVD method or the like, so that the inner wall barrier metal layer 15 prevents the copper material in the copper wiring 18 from being diffused in the insulation film 12. In this embodiment, the inner wall barrier metal layer 15 is made of, for example, TaN.

The upper barrier metal layer 19 covers an upper surface 18a of the copper wiring 18. The upper barrier metal layer 19 is made of the same material as the inner wall barrier metal layer 15. The width of the upper barrier metal layer 19 is larger than the width of the upper surface 18a of the copper wiring 18.

The copper wiring 18 connects the LDMOS element 32 as a power device. The width of the copper wiring 18 becomes wider as it goes to an upper layer. Thus, the width of the upper barrier metal layer 19 in the LDMOS element 32 becomes wider as it goes to the upper layer. Specifically, the width of the copper wiring 18 in the third wiring layer 35 is larger than that in the second wiring layer 34, and the width of the copper wiring 18 in the second wiring layer 34 is larger than that in the first wiring layer 33. Thus, the width of the upper barrier metal layer 19 in the third wiring layer 35 is larger than that in the second wiring layer 34, and the width of the upper barrier layer 19 in the second wiring layer 34 is larger than that in the first wiring layer 33.

To minimize the dimensions of the device 1, a required wiring width in the CMOS element 31 is small. Thus, the width of the copper wiring 18 in the CMOS element 31 is set to be in a range between 0.5 μm and 1.0 μm.

Here, an aspect ratio of the copper wiring 18, i.e., a ratio between the thickness of the copper wiring 18 and the width of the copper wiring 18 is set to be equal to or smaller than two. In this case, embedding property such as embedding strength of the copper wiring 18 into the wiring groove 13 is improved.

Each of the second wiring layer 34 and the third wiring layer 35 includes the interlayer insulation film 12, the inner wall barrier metal layer 15, the copper wiring 18 and the upper barrier metal layer 19, so that the second and third wiring layers 34, 35 have substantially the same structure as the first wiring layer 33.

The second wiring layer 34 is formed on an upper surface of the first wiring layer 33, which is a lower layer of the second wiring layer 34. The upper surface 18a of the copper wiring 18 in the first wiring layer 33 and a lower portion of the copper wiring 18 in the second wiring layer 34 are electrically connected to each other through the upper barrier metal layer 19 and the inner wall barrier metal layer 15.

The third wiring layer 35 is formed on an upper surface of the second wiring layer 34, which is a lower layer of the third wiring layer 35. The upper surface 18a of the copper wiring 18 in the second wiring layer 34 and a lower portion of the copper wiring 18 in the third wiring layer 35 are electrically connected to each other through the upper barrier metal layer 19 and the inner wall barrier metal layer 15.

In the semiconductor device 1, the upper barrier metal layer 19 covers the upper surface 18a of the copper wiring 18. The copper material in the copper wiring 18 is prevented from diffusing into the insulation film 12.

The upper barrier metal layer 19 is not removed from the copper wiring 18 since adhesiveness between the copper wiring 18 and the insulation film 12 is strong.

Further, it is not necessary for forming a passivation film between the copper wiring 18 and the insulation film 12 to cover the upper surface 18a of the copper wiring 18. Accordingly, it is not necessary to add an anneal process, a plasma process or the like for reforming the upper surface 18a of the copper wiring 18.

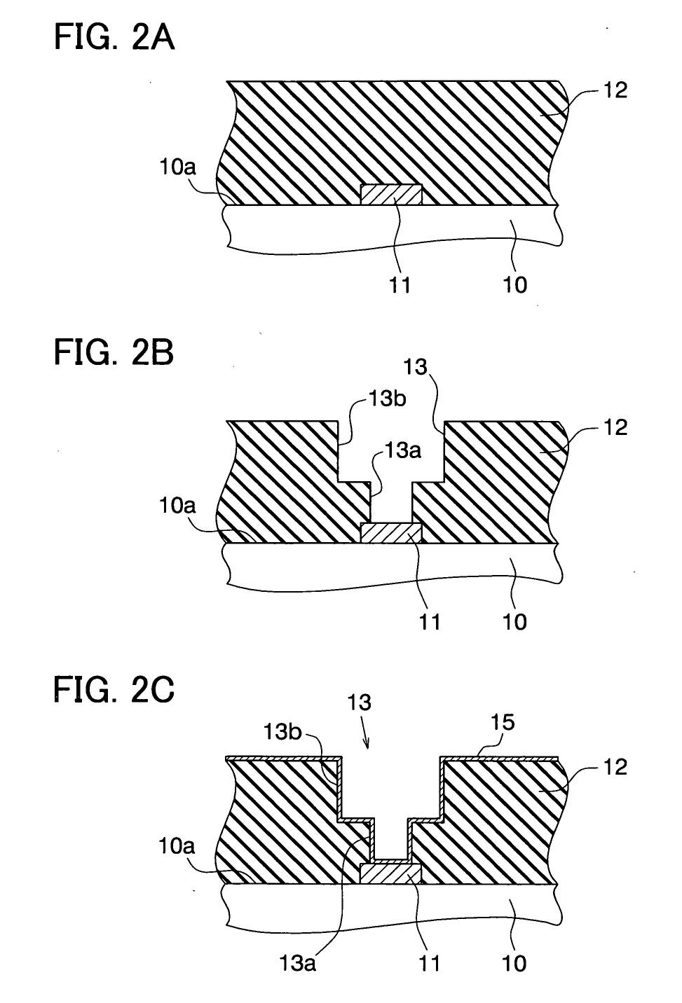

The forming method of the copper wiring 18 will be explained as follows. Here, the copper wiring 18 for each of the CMOS element 31 and the LDMOS element 32 in each of the first to third wiring layers 33-35 is formed by the same method. FIGS. 2A to 4B show the forming method of the copper wiring 18 for the CMOS element 31 in the first wiring layer 33.

As shown in FIG. 2A, the insulation film 12 is formed on the substrate surface 10a of the semiconductor substrate 10 to cover the substrate wiring 11. The insulation film 12 is made of, for example, a SiO₂ film having a thickness of 1.5 μm.

As shown in FIG. 2B, the wiring groove 13 is formed in the insulation film 12 by a photo lithography method and an etching method. The wiring groove 13 is disposed over the substrate wiring 11. The wiring groove 13 includes the via portion 13a and the wiring portion 13b. Thus, the substrate wiring 11 is exposed from the insulation film 12 so that the substrate wiring 11 is connected to the via portion 13a.

As shown in FIG. 2C, the inner wall barrier metal layer 15 made of TaN is formed on the surface of the insulation film 12, the inner wall of the wiring groove 13 and the substrate wiring 11 by a sputtering method, the CVD method or the like.

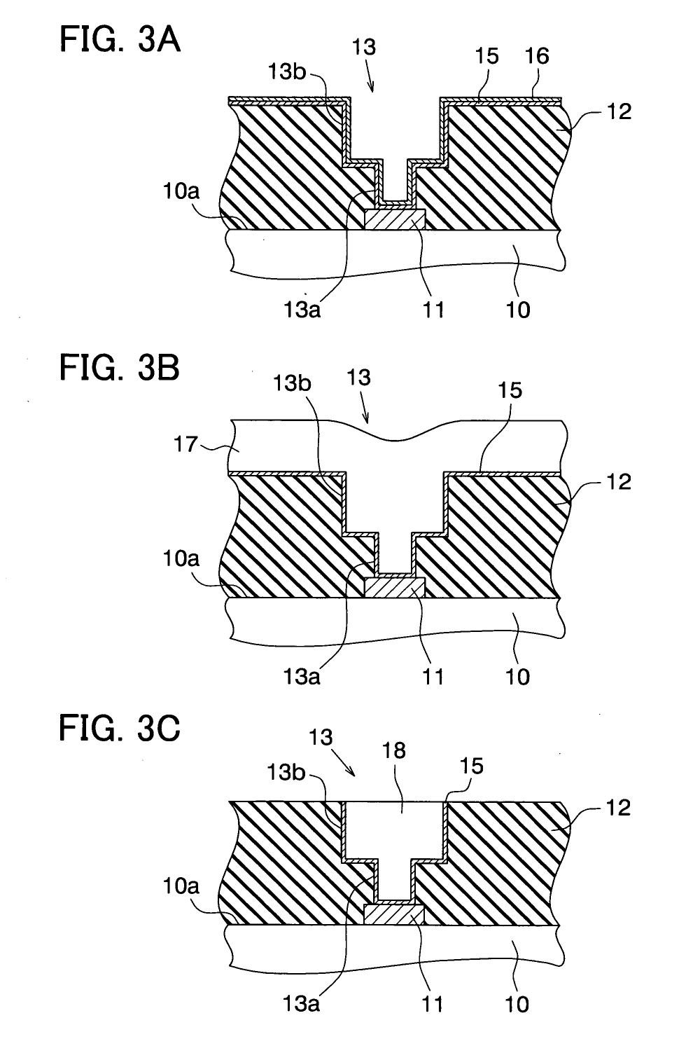

As shown in FIG. 3A, the seed layer 16 made of a copper film is formed on the inner wall barrier metal layer 15 by a sputtering method. Specifically, the seed layer 16 covers the surface of the insulation film 12, the inner wall of the wiring groove 13 and the substrate wiring 11. The seed layer 16 functions as an electrode for an electrolytic plating step.

As shown in FIG. 3B, in the electrolytic plating step, the copper plating layer 17 is formed on the substrate 10 so that the wiring groove 13 is filled with the copper material for the copper wiring 18. The seed layer 16 is integrated with the copper plating layer 17. The copper plating layer 17 may be made of pure copper, copper alloy such as Cu—Al alloy, or the like.

As shown in FIG. 3C, a part of the copper plating layer 17 on the surface of the insulation film 12, which is an excess part, is removed by the CMP method so that the insulation film 12 is flattened. Thus, the copper wiring 18 is embedded in the wiring groove 13.

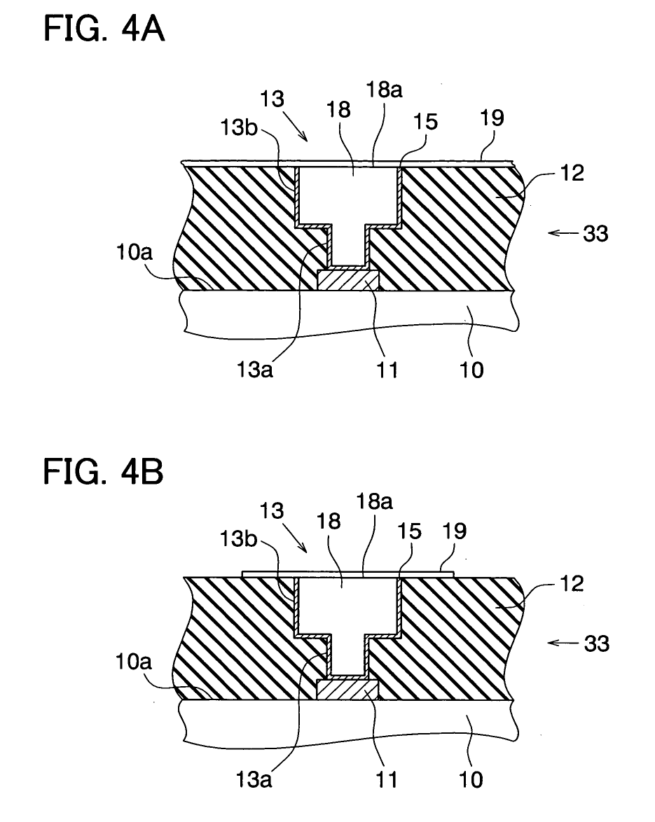

As shown in FIG. 4A, the upper barrier metal layer 19 made of TaN is formed on the insulation film 12 and the upper surface 18a of the copper wiring 18 by the sputtering method, the CVD method or the like.

As shown in FIG. 4B, a part of the upper barrier metal layer 19 remains, the part which covers the upper surface 18a of the copper wiring 18 and is wider than the copper wiring 18. The other part of the upper barrier metal layer 19 is removed by the photo lithography method and the etching method.

By repeating the above steps shown in FIGS. 2A to 4B, the second and third wiring layers 34-35 are formed, so that multiple wiring layers 33-35 are formed in the device 1.

Although the device 1 includes three wiring layers 33-35, the device 1 may include at least one wiring layer or multiple wiring layers. The thickness of the insulation film 12 may be different from 1.5 μm.

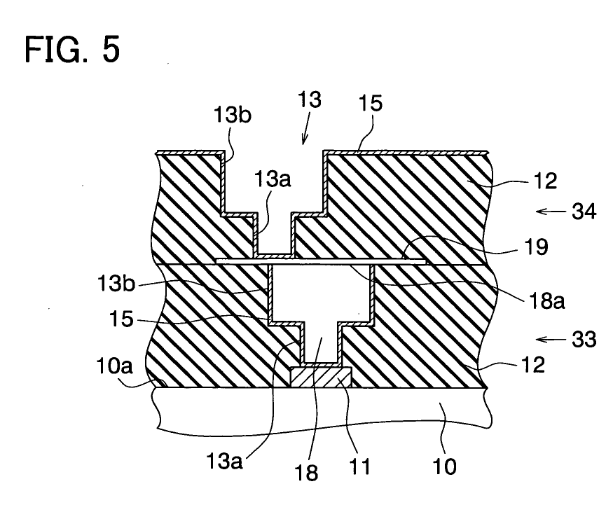

In this embodiment, the width of the upper barrier metal layer 19 is larger than the width of the upper surface 18a of the copper wiring 18. As shown in FIG. 5, in a case where the wiring groove 13 is formed in the insulation film 12 of the second wiring layer 34 by etching the insulation film 12 toward the copper wiring 18 in the first wiring layer 33, even when alignment of the wiring groove 13 deviates from a proper position so that the wiring groove 13 deviates from the upper surface 18a of the copper wiring 18 in the first wiring layer 33, the upper barrier metal layer 19 functions as an etching stopper layer. Therefore, the insulation film 12 in the first wiring layer 33 is not etched.

Accordingly, the insulation film 12 in the first wiring layer 33 is not etched excessively. Thus, erosion or migration attributed to coverage failure of the inner wall barrier metal layer 15 is prevented.

In this embodiment, the alignment accuracy of the wiring groove 13 is in a range between −0.05 μm and +0.05 μm. The width of the copper wiring 18 is 1.0 μm. Accordingly, 5% of deviation in the alignment of the wiring groove 13 may arise. Thus, preferably, the width of the upper barrier metal layer 19 may be larger than 105% of the width of the upper surface 18a of the copper wiring 18.

In a case where the width of the copper wiring 18 is smaller than 1.0 μm, even when the alignment deviates, the width of the upper barrier metal layer 19 is set to be larger than 105% of the width of the upper surface 18a of the copper wiring 18 so that the upper barrier metal layer 19 functions as an etching stopper layer.

Although the upper barrier metal layer 19 is made of TaN, the upper barrier metal layer 19 may be made of another material that prevents the copper material in the copper wiring 18 from diffusing into the insulation film 12, and that adhesiveness between the upper barrier metal layer 19 and the copper wiring 18 and adhesiveness between the upper barrier metal layer 19 and the insulation film 12 are strong. For example, the upper barrier metal layer 19 may be made of Ti, TiN, Ta, TiW, W, Ni, or Pd. The upper barrier metal layer 19 may be a multi-layer. Further, the inner wall barrier metal layer 15 may be made of material different from the upper barrier metal layer 19.

When the upper barrier metal layer 19 is made of Ni or Pd, the upper barrier metal layer 19 may be formed by a plating method. When the upper barrier metal layer 19 is formed by the plating method, the upper barrier metal layer 19 may be formed by a selective plating method. In this case, a resist is formed on the insulation film 12, and then, a plating layer corresponding to the upper barrier metal layer 19 is formed on the resist having a predetermined pattern. These steps are replaced to the steps shown in FIGS. 4A and 4B. In this case, after the plating layer is formed, the photo lithography process and the etching process are not necessary.

Although the copper wiring 18 is formed by the dual damascene method, the copper wiring 18 may be formed by a single damascene method.

In the semiconductor device 1, the upper barrier metal layer 19 is formed to cover the upper surface 18a of the copper wiring 18. The copper material in the copper wiring 18 is prevented from diffusing into the insulation film, 12.

Further, the upper barrier metal layer 19 is not removed since the adhesiveness of the copper wiring 18 and the insulation film 12 is strong.

Furthermore, it is not necessary to form the passivation film between the copper wiring 18 and the insulation film 12, and thereby, it is not necessary to add the anneal process or the plasma process for improving the surface of the copper wiring 18.

Since the width of the upper barrier metal layer 19 is larger than the width of the upper surface 18a of the copper wiring 18, the upper barrier metal layer 19 functions as an etching stopper layer in a step for forming the wiring groove 13 in the insulation film 12 of the second wiring layer 34 by etching the insulation layer 12 toward the copper wiring 18 of the first wiring layer 33 even when the alignment of the wiring groove 13 deviates from a proper position so that the wiring groove 13 deviates from the upper surface 18a of the copper wiring 18 in the first wiring layer 33. Accordingly, the insulation film 12 in the first wiring layer 33 is not etched excessively. Thus, erosion or migration attributed to coverage failure of the inner wall barrier metal layer 15 is prevented.

### Second Embodiment

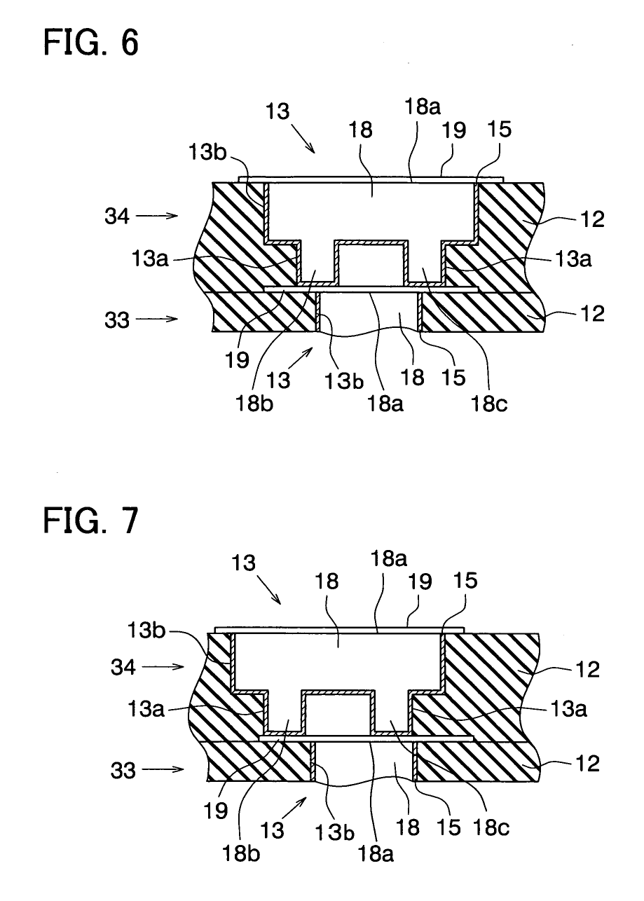

A semiconductor device 1 according to a second embodiment is shown in FIG. 6. The copper wiring 18 in the second wiring layer 34 includes multiple via wirings 18b, 18c, which electrically connects to the copper wiring 18 in the first wiring layer 33. In this embodiment, the copper wiring 18 includes two via wirings 18b, 18c.

Each via wiring 18b, 18c is disposed over the upper surface 18a of the copper wiring 18 in the first wiring layer 33. Each via wiring 18b, 18c is electrically connected to the copper wiring 18 in the first wiring layer 33. Thus, even when one of the via wirings 18b, 18c is broken so that the one has open circuit failure, the other via wiring 18b, 18c is electrically connected to the copper wiring 18 in the first wiring layer 33. Thus, electrical connection of the copper wiring 18 property functions.

Further, the copper wiring 18 in the second wiring layer 34 is connected to the copper wiring 18 in the first wiring layer 33 through the via wirings 18b, 18c such that connection by using the via wirings 18b, 18c provides parallel connection resistance. Thus, the resistance at the connection by the via wirings 18b, 18c is reduced.

In a case where the insulation film 12 in the second wiring layer 34 is etched toward the copper wiring 18 in the first wiring layer 33 so that the wiring groove 13 in the second wiring layer 34 is formed, even when the alignment of the groove 13 deviates from a proper position, one of the via wirings 18b, 18c is arranged on the upper surface 18a of the copper wiring 18 in the first wiring layer 33, and thereby, the copper wiring 18 in the second wiring layer 34 is electrically connected to the copper wiring 18 in the first wiring layer 33.

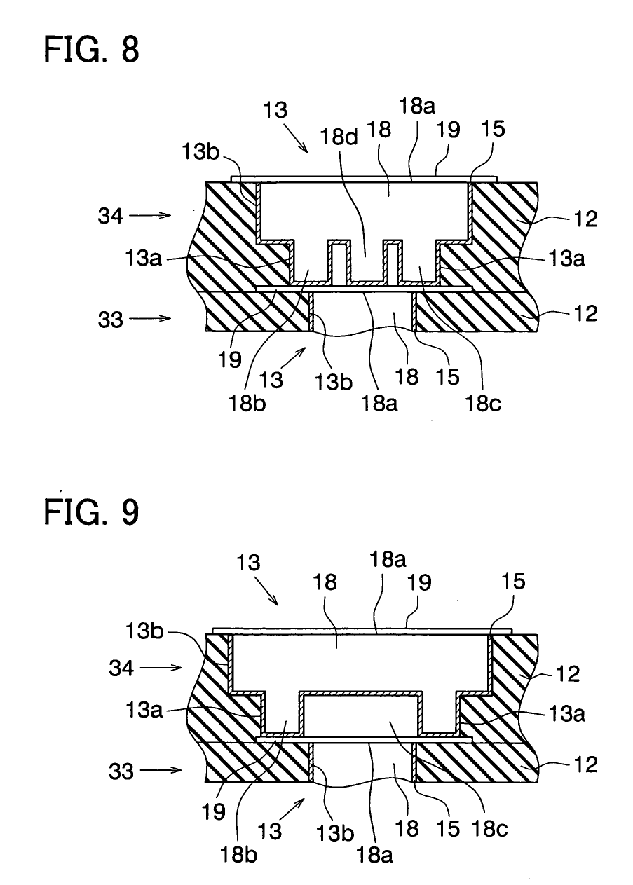

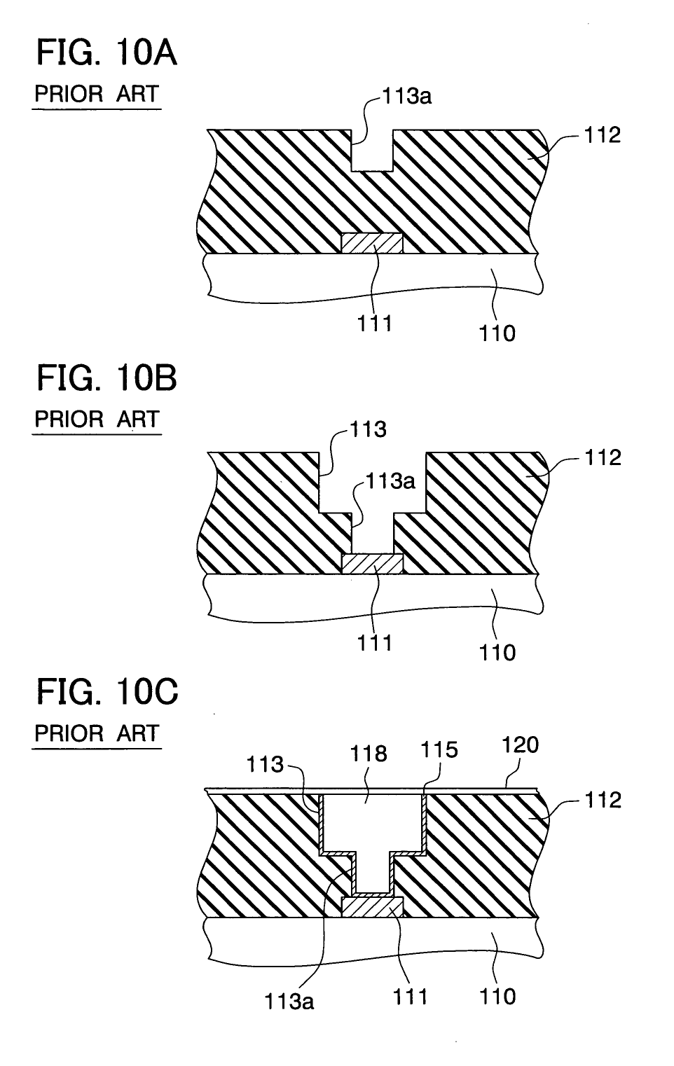

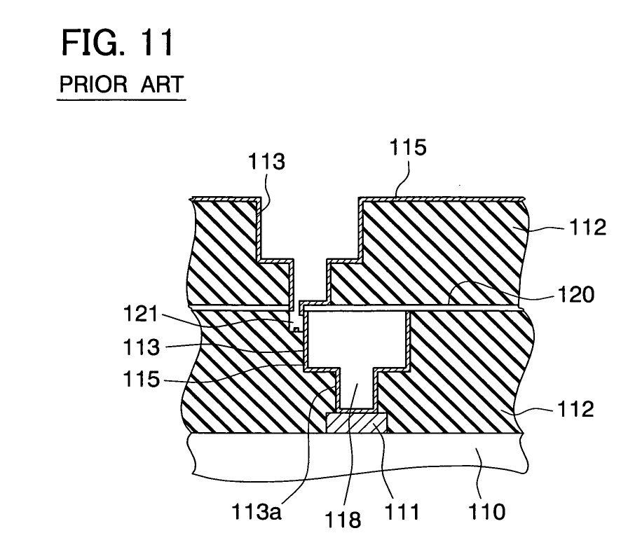

Although the copper wiring 18 in the second wiring layer 34 includes two via wirings 18b, 18c, the copper wiring 18 may have three or more via wirings. For example, as shown in FIG. 8, the copper wiring 18 has three via wirings 18b-18d. In this case, one of the three via wirings 18b-18d is surely disposed over the upper surface 18a of the copper wiring 18 in the first wiring layer 33. Thus, the copper wiring 18 in the second wiring layer 34 is electrically connected to the copper wiring 18 in the first wiring layer 33.

Even when the via wirings 18b, 18c are not disposed directly above the upper surface 18a of the copper wiring 18, as shown in FIG. 9, one of the via wirings 18b, 18c is disposed directly above the upper barrier metal layer 19 so that the copper wiring 18 in the second wiring layer 34 is electrically connected to the copper wiring 18 in the first wiring layer 33 through the upper barrier metal layer 19.

In this embodiment, in a case where the insulation film 12 in the second wiring layer 34 is etched toward the copper wiring 18 in the first wiring layer 33 so that the wiring groove 13 in the second wiring layer 34 is formed, even when the alignment of the groove 13 deviates from a proper position, one of the via wirings 18b, 18c is arranged on the upper surface 18a of the copper wiring 18 in the first wiring layer 33, and thereby, the copper wiring 18 in the second wiring layer 34 is electrically connected to the copper wiring 18 in the first wiring layer 33.

Even when one of the via wirings 18b, 18c is broken so that the one has open circuit failure, the other via wiring 18b, 18c is electrically connected to the copper wiring 18 in the first wiring layer 33. Thus, electrical connection of the copper wiring 18 property functions.

Even when the via wirings 18b, 18c are not disposed directly above the upper surface 18a of the copper wiring 18, as shown in FIG. 9, one of the via wirings 18b, 18c is disposed directly above the upper barrier metal layer 19 so that the copper wiring 18 in the second wiring layer 34 is electrically connected to the copper wiring 18 in the first wiring layer 33 through the upper barrier metal layer 19.

(Modifications)

The upper barrier metal layer 19 may be made of insulation material such as Al₂O₃, AlN by a sputtering method, a CVD method or the like.

In this case, when the wiring groove 13 in an upper wiring layer is formed by a photo lithography method and an etching method, a part of the upper barrier metal layer 19 covering the upper surface 18a of the copper wiring 18 is removed, so that the upper surface 18a of the copper wiring 18 is exposed from the layer 19. Thus, the copper wiring 18 in the upper wiring layer is electrically connected to the upper surface 18a of the copper wiring 18 in the lower wiring layer.

The upper surface 18a of the copper wiring 18 may be processed by a plasma processing method so that the upper surface 18a is reformed. For example, by using a nitrogen plasma processing method, the upper surface 18a of the copper wiring 18 is nitrided so that the upper surface 18a is stabilized. Alternatively, a N ion or a B ion is implanted on the upper surface 18a, and then, the upper surface 18a is annealed so that the upper surface 18a is reformed.

In the above cases, adhesiveness between the upper surface 18a of the copper wiring 18 and the upper barrier metal layer 19 is much improved.

While the invention has been described with reference to preferred embodiments thereof, it is to be understood that the invention is not limited to the preferred embodiments and constructions. The invention is intended to cover various modification and equivalent arrangements. In addition, while the various combinations and configurations, which are preferred, other combinations and configurations, including more, less or only a single element, are also within the spirit and scope of the invention.

What is claimed is:

1. A semiconductor device comprising:
a semiconductor substrate; and
a plurality of wiring layers staked on the substrate, wherein
each wiring layer includes:
an interlayer insulation film having a wiring groove with a via hole, which penetrates the interlayer insulation film along with a thickness direction of the interlayer insulation film;
a copper wiring disposed in the wiring groove and the via hole and made of copper or copper alloy;
an inner wall barrier metal layer disposed between an inner wall of the wiring groove with the via hole and the copper wiring; and
an upper barrier metal layer disposed on the interlayer insulation film and covering an upper surface of the copper wiring,
the inner wall barrier metal layer prevents a copper component in the copper wiring from diffusing into the interlayer insulation film,
the plurality of wiring layers includes an upper layer and a lower layer,
the copper wiring of the upper layer is electrically coupled with the copper wiring of the lower layer, and
the upper barrier metal layer of the lower layer prevents a copper component in the copper wiring of the lower layer from diffusing into the interlayer insulation film of the upper layer.

2. The semiconductor device according to claim 1, wherein
the upper barrier metal layer in each wiring layer has a width, which is larger than a width of the upper surface of the copper wiring in the wiring layer.

3. The semiconductor device according to claim 1, wherein
the via hole in each wiring layer includes a plurality of via portions,
the plurality of via portions in the upper layer is disposed on the upper barrier metal layer in the lower layer, and
the copper wiring disposed in the via portions of the upper layer is electrically coupled with the copper wiring of the lower layer.

4. The semiconductor device according to claim 3, wherein
at least one of the plurality of via portions of the upper layer is disposed just above the upper surface of the copper wiring of the lower layer.

5. The semiconductor device according to claim 1, wherein
the upper barrier metal layer is made of at least one of Ti, TiN, Ta, TaN, TiW, W, Ni, and Pd.

6. A semiconductor device comprising:
a semiconductor substrate having a substrate wiring; and
first and second wiring layers staked on the substrate in this order, wherein
the substrate wiring is disposed on a principal surface of the substrate,
the first wiring layer includes:
a first interlayer insulation film having a first wiring groove with a first via hole, wherein the first via hole penetrates the first interlayer insulation film along with a thickness direction of the first interlayer insulation film so that the first via hole reaches the substrate wiring on the substrate;
a first copper wiring disposed in the first wiring groove and the first via hole;
a first inner wall barrier metal layer disposed between an inner wall of the first wiring groove with the first via hole and the first copper wiring, and disposed on a part of the substrate wiring, wherein the part of the substrate wiring is exposed in the first via hole; and
a first upper barrier metal layer disposed on the first interlayer insulation film and covering an upper surface of the first copper wiring,
the second wiring layer includes:
a second interlayer insulation film having a second wiring groove with a second via hole, wherein the second via hole penetrates the second interlayer insulation film along with a thickness direction of the second interlayer insulation film so that the second via hole reaches the first upper barrier metal layer in the first wiring layer;
a second copper wiring disposed in the second wiring groove and the second via hole;
a second inner wall barrier metal layer disposed between an inner wall of the second wiring groove with the second via hole and the second copper wiring, and disposed on a part of the first upper barrier metal layer, wherein the part of the first upper barrier metal layer is exposed in the second via hole; and
a second upper barrier metal layer disposed on the second interlayer insulation film and covering an upper surface of the second copper wiring,
the first inner wall barrier metal layer prevents a copper component in the first copper wiring from diffusing into the first interlayer insulation film, and the second inner wall barrier metal layer prevents a copper component in the second copper wiring from diffusing into the second interlayer insulation film,
the second copper wiring is electrically coupled with the first copper wiring, and
the first upper barrier metal layer prevents a copper component in the first copper wiring from diffusing into the second interlayer insulation film.

7. The semiconductor device according to claim 6, wherein
the first upper barrier metal layer has a width, which is larger than a width of the upper surface of the first copper wiring, and
the second upper barrier metal layer has a width, which is larger than a width of the upper surface of the second copper wiring.

8. The semiconductor device according to claim 6, wherein
the first via hole includes a plurality of first via portions, and the second via hole includes a plurality of second via portions,
the plurality of second via portions is disposed on the first upper barrier metal layer, and
the second copper wiring disposed in the second via portions is electrically coupled with the first copper wiring.

9. The semiconductor device according to claim 8, wherein
at least one of the plurality of second via portions is disposed just above the upper surface of the first copper wiring.

10. The semiconductor device according to claim 6, wherein
the upper barrier metal layer is made of at least one of Ti, TiN, Ta, TaN, TiW, W, Ni, and Pd.
